(19) United States
(12) Patent Application Publication
(10) Pub. No.: US 2026/0182431 A1
(43) Pub. Date: Jun. 25, 2026

(54) System-integrated three-dimensional fan-out 3DFO Structure

(71) Applicant: SJ Semiconductor(Jiangyin) Corporation, Jiangyin (CN)

(72) Inventors: Yenheng CHEN, Jiangyin (CN); Chengchung LIN, Jiangyin (CN)

(73) Assignee: SJ Semiconductor(Jiangyin) Corporation, Jiangyin, JS (CN)

(21) Appl. No.: 19/125,761

(22) PCT Filed: Oct. 27, 2023
(86) PCT No.: PCT/CN2023/127211

§ 371 Date: Apr. 30, 2025

(30) Foreign Application Priority Data
Dec. 29, 2022 (CN) 202223536831.X

(51) Int. Cl. H10W 72/20; H10W 72/90

(52) U.S. Cl. CPC H10W 72/20; H10W 72/952

(57) ABSTRACT

A system-integrated 3DFO structure, including a first rewiring layer, which has a first wiring dielectric layer and a first wiring metal layer located in the first wiring dielectric layer, first metal columns, over the first rewiring layer and electrically connected to the first wiring metal layer; a SOC face-up bonded to the first surface of the first rewiring layer; a first plastic sealing layer, covering the SOC, the first metal columns, and exposing the SOC and the first metal columns; a second rewiring layer over the first plastic sealing layer; first external interfaces, located on a surface of the second rewiring layer away from the first metal columns; a top chip, on the first rewiring layer and electrically connected to the first wiring metal layer; a second plastic sealing layer, covering the top chip and the first rewiring layer.

### FIELD OF TECHNOLOGY

The present disclosure relates to semiconductor packaging, in particular, to a system-integrated 3DFO structure.

### BACKGROUND OF THE INVENTION

With advancements in technology, end-users demand smaller, faster, and more energy-efficient devices, leading to a major trend in developing higher performance, more miniaturized and multi-functional electronic terminal products in the semiconductor industry. Therefore, how to integrate and package several different kinds of high-density chips together to form a system or subsystem that is powerful and has a small volume and power consumption has become a real challenge in the field of advanced packaging of semiconductor chips.

System-level packaging, as an emerging heterogeneous integration technology, is becoming increasingly popular for chip packaging. It integrates multiple functional chips and components into a single package, to provide a complete system which brings a short development cycle, boosted functionality, reduced power consumption, superior performance, and a more compact form-factor.

To meet the increasingly higher requirements for packaging components and functions, there is an urgent need for an ultra-highly integrated system-level packaging technique. This preferred structure is desired to be capable of integrating different generations of System-on-Chips (SOCs) within a single packaging structure, realizing a multifunctional system working in concert, and enhancing the functional density, and is featured with high compatibility, elevated integration levels, and exceptional flexibility.

### SUMMARY OF THE INVENTION

The present disclosure provides a system-integrated 3DFO structure with the following beneficial effects: the SOC thereof is a system-stacked 3D packaging structure, which integrates system chips or wafers of different generations in the same packaged chip by means of hybrid bonding, and according to the different size and dimension characteristics of the system chips or wafers of different generations, the low-generation system chips are stacked on the high-generation system chips, so that more functions can be realized in the packaging structure of the same size, which greatly improves the functional density of the packaging structure and optimizes the wafer size; the SOC is applied to the 3DFO packaging structure to form a system-integrated 3DFO structure, integrating capacitors, resistors, inductors, transistors, GPUs, PMUs, DDRs, flash memory, filters and/or other electronic chips and components, accommodating more cooperating functional systems in the packaging structure without increasing the size of the structure, eliminating the need to separately prepare multiple packaging structures, avoiding additional packaging structure connections, saving production process costs, improving the chip performance of system-integrated 3DFO structures, enhancing the economic benefits of system-integrated 3DFO structures, comprising high compatibility, elevated integration levels, and exceptional flexibility; the use of the metal columns for the power supply of the entire packaging structure and the transmission of electrical signals, eliminating the need for silicon through-holes, and providing a more stable transmission of electrical power and a lower time delay, ultimately boosting the stability and dependability of the packaging configuration.

The first signal interfaces of the first chip in the SOC are electrically connected to the corresponding interfaces of the system wafer by directly aligning the first metal pads with the second metal pads. This shortens the electrical connection paths, lowers parasitic capacitance within the packaging structure, and enhances signal transmission efficiency; the spacing between the first metal pads, and the spacing between the second metal pads may be extended to less than 5 μm, so that the number of metal pads may be increased per unit area, thereby increasing the number of data channels, increasing data throughput, and improving integration; The width of the first metal pads and the second metal pads doesn't have to be identical, addressing issues with accuracy in hybrid bonding chip placement and ultimately enhancing production efficiency.

### BRIEF DESCRIPTION OF THE DRAWINGS

FIGS. 1a to 4 show schematic diagrams of intermediate structures obtained after various steps of a method of SOC preparation process according to an embodiment of the present disclosure.

FIGS. 5-12 show schematic diagrams of intermediate structures obtained after various steps of a method of preparing a system-integrated 3DFO structure according to an embodiment of the present disclosure.

Reference Numerals

| | |
|---|---|
| 1 | First wafer |
| 11 | First chips |
| 2 | System wafer; |
| 3 | First dielectric layer |
| 4 | First metal pads |
| 5 | Second dielectric layer |
| 6 | Second metal pads |
| 7 | In-chip metal columns |
| 8 | In-chip plastic sealing layer |
| 9 | In-chip rewiring layer |
| 91 | In-chip wiring dielectric layer |
| 92 | In-chip wiring metal layer |
| 10 | External Interface |
| 100 | SOC |
| 110 | First substrate |
| 120 | First rewiring layer |
| 121 | First wiring dielectric layer |
| 122 | First wiring metal layer |
| 130 | First metal columns |
| 140 | First plastic sealing layer |
| 150 | Second rewiring layer |
| 151 | Second wiring dielectric layer |
| 152 | Second wiring metal layer |
| 160 | First external Interface |
| 170 | Top chips |
| 180 | Second plastic sealing layer |

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different specific embodiments. Various details in this specification can also be modified or changed based on different viewpoints and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width, and depth of the three-dimensional space dimensions.

It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

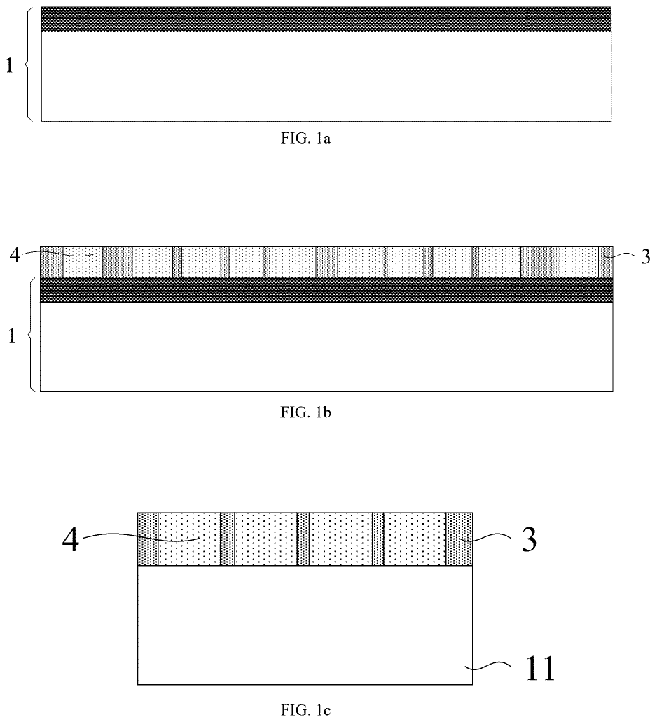

As shown in FIGS. 1a to 8, the present disclosure provides a method for preparing a system-integrated 3DFO structure, and the structure and beneficial effects of the system-integrated 3DFO structure will also be described in detail based on the method, and the method comprises the following steps.

As shown in FIGS. 1a to 1c a first wafer 1 is provided, a first dielectric layer 3 and first metal pads 4 disposed in the first dielectric layer 3 are formed on the first wafer 1, the first metal pads 4 are electrically connected to the first wafer 1, and the first chip 11 is formed by encapsulating and scribing the chip.

Specifically, as in FIG. 1a, the first wafer 1 is provided, the first wafer 1 is a wafer that has been fabricated, has a complete internal structure (not shown) and an external signal interface (not shown); it may be one of a variety of wafers, such as memory wafers capable of realizing the role of storage, such as programmable logic device wafers capable of realizing the role of programming, such as system wafers integrating information processing devices. As an example, the first wafer 1 is an earlier-generation system wafer of small size specifications. The method of SOC preparation process comprises: depositing the first dielectric layer 3 on the first wafer 1, wherein the first dielectric layer 3 is an intermetallic dielectric layer comprising one of silicon oxide, silicon nitride, silicon nitride, silicon nitride, silicon carbide, and other low K inorganic dielectric materials. The first dielectric layer 3 may also comprise an organic dielectric material formed by polymers such as Benzocyclobutene (BCB), polyimide (PI), etc. Further the first dielectric layer 3 can also be a combination of materials including an inorganic and an organic dielectric. The method further comprises: patterning the first dielectric layer 3 to define metal-pad contact holes (holes can have different sizes as shown), with the metal-pad contact holes partially exposing a first signal interfaces of the first wafer 1. The method further comprises: depositing a protective layer (not shown), on the first dielectric layer 3 including covering the internal surfaces of the metal-pad contact holes, before depositing a metal-pad layer on the protective layer in and out of the metal-pad contact holes. The preferred material for forming the metal-pad layer is copper, but it can also be other suitable metals or metal alloys such as nickel, tin, and so on. After the filling of the metal-pad contact holes are completed, the deposition of a metal layer of a certain thickness is performed on the stack of metal-pad layer, the protective layer, and the first dielectric layer 3, and then excess metal on surface of the first dielectric layer 3 is removed by a flattening process such as chemical-mechanical grinding, as shown in FIG. 1b, to obtain a flattened first dielectric layer 3 with first metal pads 4 disposed in the first dielectric layer 3. The metal-pad contact holes in the first dielectric layer 3 and the first metal pads 4 are adjusted in alignment in the patterning process to the first signal interfaces on the front side of the first wafer 1 so that the first signal interfaces are electrically connected to the first metal pads 4, wherein the first metal pads 4 are arranged differently from the first signal interfaces. The method further comprises: removing materials in wafer 1 outside individual first chips 11 and then sealing the remaining first wafer 1 with the first chip 11, as shown in FIG. 1c. Thus, completing the system wafer 1.

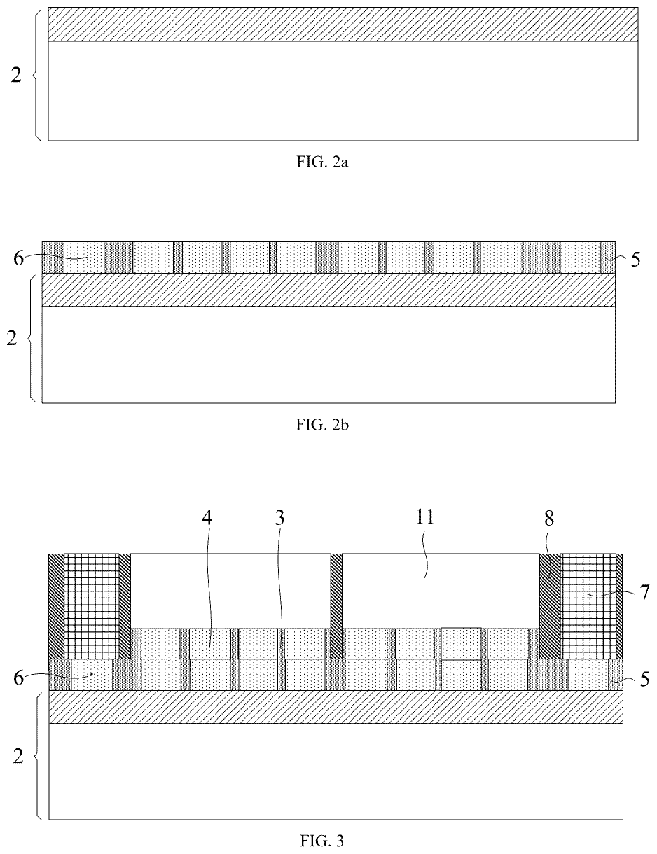

As shown in FIGS. 2a to 2b, a system wafer 2 is provided, a second dielectric layer 5 and second metal pads 6 disposed in the second dielectric layer 5 are formed on the system wafer 2, and the second metal pads 6 are electrically connected to the system wafer 2.

Specifically, as in FIG. 2a, the system wafer 2 is an advanced-generation system wafer, with a large size. Second signal interfaces are provided on surfaces of the system wafer 2. As in FIG. 2b, a second dielectric layer 5 and second metal pads 6 disposed in the second dielectric layer 5 are formed over the system wafer 2. The second dielectric layer 5 and the second metal pads 6 can be patterned to align to the second signal interfaces on the front side of the system wafer 2 so that the second signal interfaces are electrically connected to the second metal pads 6, wherein the second metal pads 6 are arranged differently from the second signal interfaces. The specific method of forming the second dielectric layer 5 and the second metal pads 6 is substantially the same as the method of forming the first dielectric layer 3 and the first metal pads 4 described above.

As shown in FIG. 3, in-chip metal columns 7 are formed on the second metal pads 6 and in-chip plastic sealing layers 8 are formed on the in-chip metal columns 7. The in-chip plastic sealing layers 8 bond sidewalls of the first chips 11 to the in-chip metal columns 7 by a hybrid bonding process. The in-chip plastic sealing layer 8 covers the sidewalls of the first chips 11, the sidewalls of the adjacent in-chip metal columns 7, and the adjacent second dielectric layer 5. In some situations, the bottom surface of the in-chip metal columns 7 are partially exposed. As a result, the stack of the first system wafer 1 including the first chips 11 and the first dielectric layer 3 and first metal pad layer 4 is firmly attached to the stack of the system wafer 2 which includes the dielectric layer 5, the metal pads layer 6 on the top surface of the wafer 2.

Specifically, as an example, the in-chip metal columns 7 are formed on peripheral ones of the second metal pads 6, and the in-chip metal columns 7 are electrically connected to the second signal interfaces of the system wafer 2 through the second metal pads 6 to provide power transmission and signal transmission; this approach enhances the integration of the first chips 11 on the system wafer 2 by freeing up more space and optimizing the overall wafer size. According to actual layout requirements, the in-chip metal columns 7 may also be located only over those second metal pads 6 at one side of one first chip 11, or over those second metal pads 6 in the middle of the system wafer 2.

The material of the in-chip metal columns 7 comprise, but are not limited to, one of copper and titanium. The columns may be formed by one or more of Physical Vapor Deposition (PVD), Chemical Vapor Deposition (CVD), sputtering, electroplating and chemical plating. As an example, a PVD process is used to form a copper layer, then photoresist is disposed on the copper layer, the photoresist is then patterned, then the copper layer is etched, to finally form the metal columns 7 on the peripheral ones of the second metal pads 6, followed by removing the photoresist.

The first chip 11 is bonded to the system wafer 2 through a hybrid bonding method, where corresponding bonding occurs between the first metal pads 4 and the second metal pads 6, and between the first dielectric layer 3 and the second dielectric layer 5.

In detail, hybrid bonding combines metal-to-metal bonding and dielectric-to-dielectric bonding, wherein the first signal interfaces of the first chip 11 are directly electrically connected to corresponding interfaces of the system wafer 2 through the bonding of the first metal pads 4 and the second metal pads 6, thereby reducing the electrical connection paths, decreasing the parasitic capacitance in the packaging structure, and improving the signal transmission efficiency between the first chip 11 and the system wafer 2; while obtaining vertical metal interconnections, the additional use of dielectric bonding serves to enhance the physical mechanical performance between stacked chips, thereby improving the overall performance of the stacked chips. In detail, the hybrid bonding technology is different from the traditional bump bonding technology in that the former doesn't involve prominent bumps, and instead, surfaces of the dielectric layer are exceptionally smooth. By attaching the two chips together at room temperature, increasing the temperature and annealing them, the copper expands and bonds together firmly, thereby forming an electrical connection with high current loading capacity and low interconnect length, reducing power consumption per interconnect channel, and obtaining a low time delay; In addition to the metal bonding together, dielectric layers also bond together, with no more spacing between the dielectric layers and no need for filler adhesive, leading to better heat dissipation performance and bonding strength. In the figures, the first chips 11 may include more than one chips, depending on the actual functional requirements. The integration of different generations of system chips or wafers in the same package is realized by hybrid bonding of the first chips 11 with the system wafer 2, effectively utilizing the dimensional characteristics of different generations of chips. As high-generation chips have larger sizes and low-generation chips have smaller sizes, stacking different generations of system chips allows for stacking low-generation system chips over high-generation ones. This achieves the incorporation of more functionalities within the same packaging dimensions, greatly improving the functional density of the packaging structure, optimizing chip sizes, offering high flexibility, and exhibiting extensive compatibility.

The material of the in-chip plastic sealing layer 8 may include one or more of epoxy-based resins, liquid thermosetting epoxy resins, and plastic molding compounds, and may be formed by one or more of, compression molding, transfer molding, liquid-seal potting molding, vacuum lamination, spin-coating, and other suitable methods. After forming the in-chip plastic sealing layer 8, a flattening process is employed to ensure that top surfaces of the in-chip metal columns 7 are flush with a top surface of the in-chip plastic sealing layer 8.

As an example, the dimensions of the first metal pads 4 are not necessarily the same as the dimensions of the second metal pads 6.

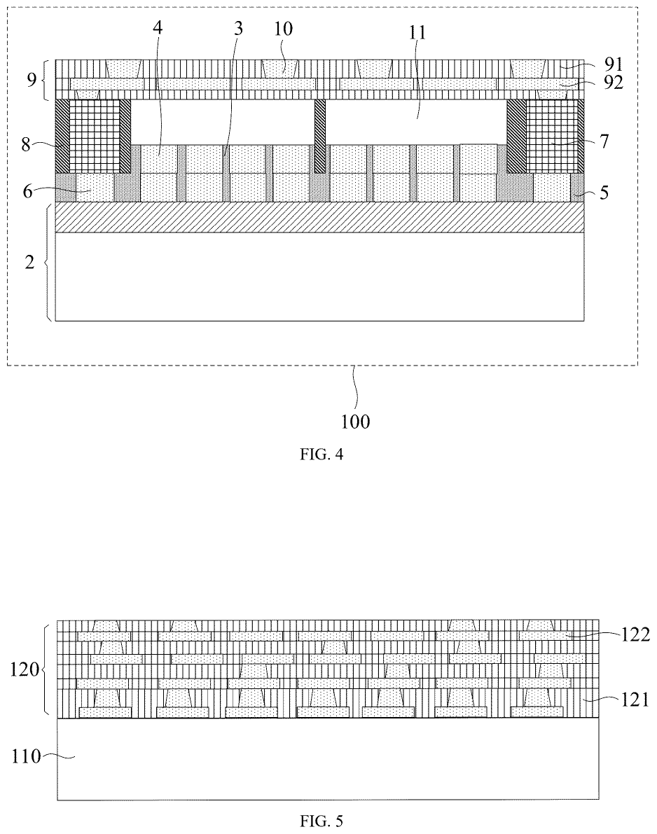

Specifically, as shown in FIG. 4, as an example, the first metal pads 4 have the same dimensions as the second metal pads 6 and are aligned after they are bonded. However, sizes of the first metal pads 4 and the second metal pads 6 may not be the same in actual situation. The first metal pads 4 may have a larger size and the second metal pads 6 has a smaller size; or the size of the second metal pads 6 can be larger than the size of the first metal pads 4. This flexible approach can overcome precision issues during hybrid bonding, reduce bonding complexity, and enhance production efficiency.

As an example, the spacing between two adjacent first metal pads 4 can be arranged less than 5 μm, and the spacing between two adjacent second metal pads 6 is less than 5 μm.

Specifically, as an example, for those conventional structures that the spacing between the two adjacent first metal pads 4, or the spacing between the two adjacent second metal pads 6 exceeds 10 μm, they can be reduced to less than 5 μm, so that the number of metal pads can be increased per unit area, thereby increasing the number of data channels and, consequently, improving data throughput, functional density, and degree of packaging integration. As an example, the spacing between two adjacent first metal pads 4 can be made 3 μm and the spacing between two adjacent second metal pads 6 also can be made 3 μm. As another example, the spacing between two adjacent first metal pads 4 can be also made 1 μm and the spacing between two adjacent second metal solder pads 6 can be made 1 μm.

As shown in FIG. 4, an in-chip rewiring layer 9 is formed over the in-chip plastic sealing layer 8 and the first chips, the in-chip rewiring layer 9 comprises an in-chip wiring dielectric layer 91 and an in-chip wiring metal layer 92 located in the in-chip wiring dielectric layer 91 and electrically connected to the in-chip metal columns 7, and external interfaces 10 are formed on an opposite side of the in-chip wiring metal layer 92 and the in-chip wiring dielectric layer 91 away from the first chips and the in-chip metal columns 7, thereby forming a System-on-Chip (SOC) 100.

Specifically, a material of the in-chip wiring dielectric layer 91 comprises one of epoxy resin, silicone, PI, parylene (PBO), BCB, silicon oxide, phosphosilicate glass, and fluorine-containing glass. The in-chip wiring dielectric layer 91 is patterned to partially expose the in-chip metal columns 7. The in-chip wiring metal layer 92 is formed within the in-chip wiring dielectric layer 91, and the in-chip wiring metal layer 92 is electrically connected to the in-chip metal columns 7. A material of the in-chip wiring metal layer 92 comprises one or a combination of copper, aluminum, titanium, and nickel. A technique of forming the in-chip wiring metal layer 92 comprises, but is not limited to, PVD, CVD, sputtering, electroplating, and chemical plating. The in-chip wiring metal layer 92 comprises a single-layer or multi-layer structure.

The external interfaces 10 are formed on the opposite side of the wiring metal layer 92 away from the in-chip metal columns 7. The external interfaces 10 comprise solder balls or pads. As an example, the external interfaces 10 are solder pads, for subsequent structures in a 3DFO packaging system. A material of the solder pads comprises one or more of copper, nickel, and tin.

The in-chip metal columns 7 are connected electrically to the in-chip rewiring layer 9 at the top for direct power supply to the system wafer 2 and for electrical signal transmission. Compared to traditional silicon vias, the in-chip metal columns 7 have larger dimensions and lower electric resistance, enabling more stable power transmission and lower time delays.

After forming the solder pads, in order to further reduce the height of the packaging structure, the backside of the substrate of the system wafer 2 can also be thinned and the substrate can be flattened on the backside by methods such as grinding, and then packaged to form a SOC 100. The SOC 100 is applied to a 3DFO packaging structure to form a system-integrated 3DFO structure. As a non-limiting example, a method of applying the SOC 100 to a 3DFO packaging structure is described below, and alternative methods may also be used according to the actual production needs.

As shown in FIG. 5, a first substrate 110 is provided and a separation layer (not shown) is formed on the first substrate 110, and a first rewiring layer 120 is formed on the separation layer, the first rewiring layer 120 comprises a first wiring dielectric layer 121 and a first wiring metal layer 122 located on the first wiring dielectric layer 121, and the first rewiring layer 120 has first (top) and second surface (bottom on the substrate) opposite to each other.

Specifically, the first substrate 110 is a support substrate, which may be a glass substrate, a semiconductor substrate, a polymer substrate, or a ceramic substrate; it is used to prevent problems such as cracking, warping, and fracturing of the stacked chips during subsequent preparation, and needs to be removed during subsequent processes. As an example, the first substrate 110 is a glass substrate, which is less expensive and easy to peel off from the package layers at a later stage. The separation layer is used to first adhere the first substrate 110 to the first wiring dielectric layer 121 and to later separate the first substrate 110 from the first wiring dielectric layer 121. The separation layer comprises one of a tape layer and a polymer layer, which is applied to the substrate 110 by spin coating and then cured by laser curing, ultra-violet (UV) curing, or thermal curing. The first rewiring layer 120 may prepared in the same manner as the in-chip rewiring layer 9; all wiring metal layers in this application may comprise single or multi-layer structures.

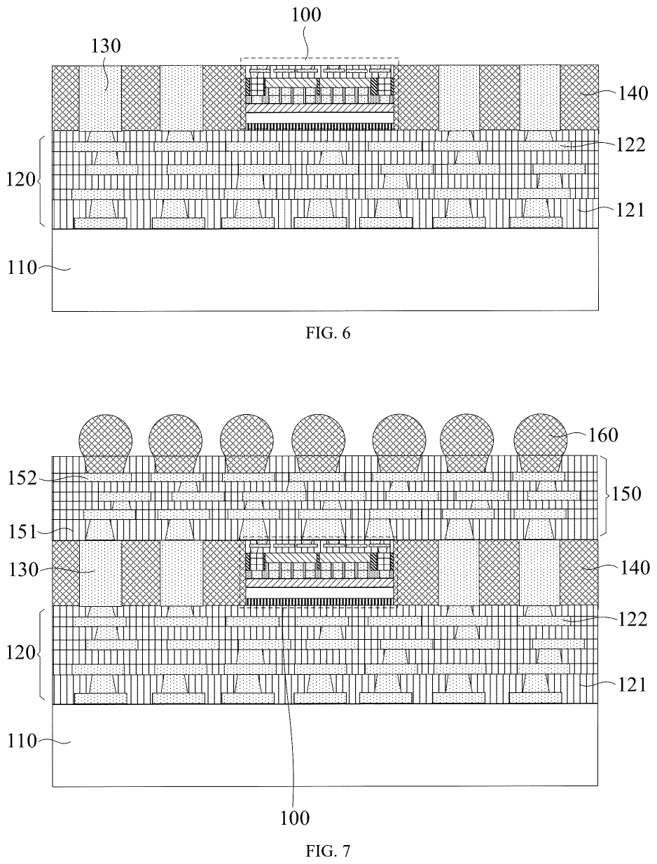

As shown in FIG. 6, first metal columns 130 are formed on the first wiring metal layer 122 on the first surface of the first rewiring layer 120, the SOC 100 is face-up bonded to the first surface of the first rewiring layer 120, and then a first plastic sealing layer 140 is formed, the first plastic sealing layer 140 covers the SOC 100, the first metal columns 130, and the first surface of the rewiring layer 120, and exposes the top surface of the SOC 100 and the top surfaces of the first metal columns 130.

The SOC 100 is provided with the external interfaces 10 on its front side (top), and the SOC 100 is bonded to the first surface on the front side that is away from the first rewiring layer 120. The bonding may be adhesive bonding, wherein the SOC 100 is fixed onto the first surface using adhesive tape or polymer as a bonding layer to prevent relative movement during subsequent manufacturing processes. The number of the SOC 100 is not limited to 1 as shown in the figures, and it can be more than one.

As shown in FIG. 7, a second rewiring layer 150 is formed over the first plastic sealing layer 140, the second rewiring layer 150 comprising a second wiring dielectric layer 151 and a second wiring metal layer 152 located in the second wiring dielectric layer 151. The second wiring metal layer 152 is electrically connected to the first metal columns 130 and the SOC 100. First external interfaces 160 are formed on a surface of the second wiring metal layer 152 away from the first metal columns 130. Similarly, the first external interfaces 160 comprise solder balls and solder pads; as an example, the first external interfaces 160 are solder balls.

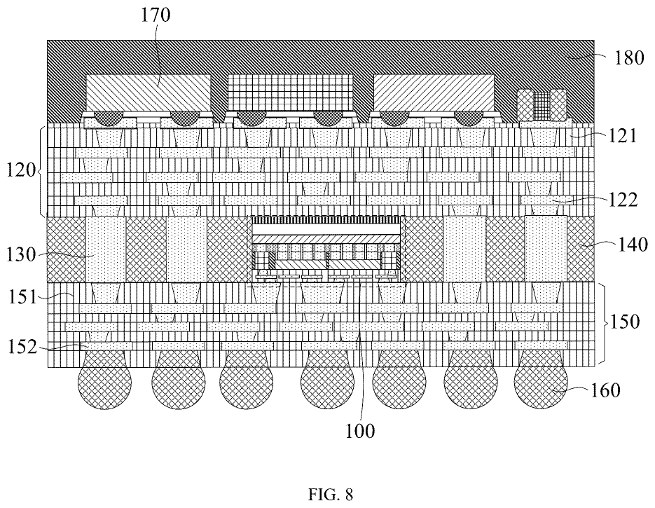

As shown in FIG. 8, the first substrate 110 was removed so the second surface of the first rewiring layer 120 is partially exposed. Top chips 170 are mounted on the first wiring metal layer 122 on the second surface of the first rewiring layer 120, and a second plastic sealing layer containing phospholipase 180 is formed encapsulating the top chips 170 and the second surface of the first rewiring layer 120.

Specifically, the intermediate structure as shown in FIG. 7 is inverted in FIG. 8, and then the first substrate 110 is removed to expose the second surface of the first rewiring layer 120 through methods such as UV exposure, heating, grinding, or wet etching on the separation layer. The top chips 170 are mounted to the first wiring metal layer 122 on the second surface of the first rewiring layer 120. The top chips 170 each may include various devices such as Graphics Processing Units (GPUs), Power Management Units (PMUs), Double-Data-Rate Synchronous Dynamic Random Access Memory (DDR), flash memory, transistors, and filters. The top chips 170 may also be passive devices such as capacitors, resistors, and inductors. In the figures, the top chips 170 are shown to comprise 3 chips, but the number of the top chips 170 may be any other number according to practical situations. After the second plastic sealing layer 180 is formed, it may be thinned and flattened as needed.

As shown in FIG. 8, the present disclosure further provides a system-integrated 3DFO structure, which may or may not be prepared by the method described above. The system-integrated 3DFO structure comprises:
a first rewiring layer 120 comprising a first wiring dielectric layer 121 and the first wiring metal layer 122 located in the first wiring dielectric layer, wherein the first wiring dielectric layer 121 comprises a first surface and a second surface opposite to the first surface;
first metal columns 130, located on the first surface of the first rewiring layer and electrically connected to the first wiring metal layer 122;
a SOC 100, face-up bonded to the first surface, which is a system stacked 3D packaging structure that comprises a system wafer 2 and first chips 11 hybrid bonded to the system wafer 2;
a first plastic sealing layer 140 that covers the SOC 100, the first metal columns 130, and the first surface of the first rewiring layer 120, and exposes the top surfaces of the SOC 100 and the first metal columns 130;
a second rewiring layer 150, formed over the first plastic sealing layer 140, comprising a second wiring dielectric layer 151 and a second wiring metal layer 152 located in the second wiring dielectric layer 151, wherein the second wiring metal layer 152 is electrically connected to the first metal columns 130 and the SOC 100;
first external interfaces 160, located on a surface of the second wiring metal layer 152 away from the first metal columns 130;
top chips 170, located on the second surface and electrically connected to the first wiring metal layer 122; and
a second plastic sealing layer 180, covering the top chips 170 and the second surface of the first rewiring layer 120.

As an example, the first chips 11 are system chips, belonging to a different or earlier generation than the one that system wafer 2 belongs to;

As an example, as shown in FIG. 4, the SOC 100 comprises:
the system wafer 2;
a second dielectric layer 5 and second metal pads 6, formed on the system wafer 2, the second metal pads 6 are located in the second dielectric layer 5 and electrically connected to the system wafer 2;
the in-chip metal columns 7, formed on some of the second metal pads 6 and electrically connected to these second metal pads 6;
the first chips 11 from an earlier generation;
a first dielectric layer 3 and first metal pads 4, formed on the first chips 11, the first metal pads 4 are located in the first dielectric layer 3 and electrically connected to the first chips 11, wherein the first dielectric layer 3 and the second dielectric layer 5 become attached with the first metal pads 4 and the second metal pads 6 correspondingly attached;
an in-chip plastic sealing layer 8, covering the sidewalls of the first chips 11, the sidewalls of the in-chip metal columns 7 and the second dielectric layer 5, partially exposing the in-chip metal columns 7;
an in-chip rewiring layer 9, formed over the in-chip plastic sealing layer 8, comprising an in-chip wiring dielectric layer 91 and an in-chip wiring metal layer 92 located in the in-chip wiring dielectric layer 91 and electrically connected to the in-chip metal columns 7; and
external interfaces 10, formed on a surface of the in-chip wiring metal layer 92 away from the in-chip metal columns 7.

As an example, the spacing between two adjacent ones of the first metal pads 4 is less than 5 μm, and the spacing between two adjacent ones of the second metal pads 6 is less than 5 μm.

As an example, the dimensions of the first metal pads 4 are not the same as the dimensions of the second metal pads 6.

As an example, the in-chip metal columns 7 are located on peripheral ones of the second metal pads 6.

As an example, a front surface of the first wafer 1 has first signal interfaces electrically connected to the first metal pads 4, and the first metal pads 4 have an arrangement different from that of the first signal interfaces; a front surface of the system wafer 2 has second signal interfaces electrically connected to the second metal pads 6, and the second metal pads 6 have an arrangement different from that of the second signal interfaces.

As an example, the first dielectric layer 3 comprises one or more of silicon oxide, silicon nitride, silicon nitride oxide, silicon carbon nitride, and polymer, and the second dielectric layer 5 comprises one or more of silicon oxide, silicon nitride, silicon nitride oxide, silicon carbon nitride, and polymer.

As an example, the substrate of the system wafer 2 is thinned and flattened.

As an example, the number of the top chips 170 is N, wherein N is an integer and N≥2.

In summary, the present disclosure provides a system-integrated 3DFO structure with the following beneficial effects: the SOC is a system-stacked 3D packaging structure, which integrates system chips or wafers of different generations in the same packaged chip by means of hybrid bonding. According to the different size and dimension characteristics of the system chips or wafers of different generations, the earlier-generation system chips are stacked on the more advanced-generation system chips, so that more functions can be realized in the packaging structure of the same size, which greatly improves the functional density of the packaging structure and optimizes the wafer size. The SOC is applied to the 3DFO packaging structure to form a system-integrated 3DFO structure, integrating passive elements like capacitors, resistors, inductors, and active transistors, GPUs, PMUs, DDRs, flash memory, filters and/or other electronic chips and components, accommodating more cooperating functional systems in the packaging structure without increasing the size of the structure, eliminating the need to separately prepare multiple packaging structures, avoiding additional packaging structure connections, saving production process costs. Therefore, it improves the chip performance of system-integrated 3DFO structures, enhances the economic benefits of system-integrated 3DFO structures. It also brings high compatibility, elevated integration levels, and exceptional flexibility. The use of the metal columns for the power supply of the entire packaging structure and the transmission of electrical signals eliminates the need for costly through-silicon-vias (TSV), and provides a more stable transmission of electrical power and a lower time delay, ultimately boosts the stability and dependability of the packaging configuration.

The first signal interfaces of the first chip in the SOC are electrically connected to the corresponding interfaces of the system wafer by directly aligning the first metal pads with the second metal pads. This shortens the electrical connection paths, lowers parasitic capacitance within the packaging structure, and enhances signal transmission efficiency. The spacing between two adjacent ones of the first metal pads, and the spacing between two adjacent ones of the second metal pads may be extended to less than 5 μm, so that the number of metal pads may be increased per unit area, thereby increasing the number of data channels, increasing data throughput, and improving integration. The widths of the first metal pads and the second metal pads don't have to be identical, which relaxes the accuracy requirements in hybrid bonding chip placement and ultimately enhancing production efficiency.

The above-mentioned embodiments are merely illustrative of the principle and effects of the present disclosure instead of restricting the scope of the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A system-integrated 3DFO structure, comprising:
a System-on-Chip (SOC);
wherein the SOC comprises a system wafer, a first chip, and an in-chip wiring layer, and wherein the first chip is hybrid bonded to the system wafer;
a first rewiring layer;
wherein the first rewiring layer comprises a first wiring dielectric layer and a first wiring metal layer located in the first wiring dielectric layer, wherein the first rewiring layer comprises a first surface and a second surface opposite to the first surface;
wherein the SOC is face-up bonded to the first surface of the first rewiring layer;
first metal columns disposed in a first plastic sealing layer;
wherein the first metal columns are located on the first surface of the first rewiring layer and electrically connected to the first wiring metal layer;
wherein the first plastic sealing layer covers the SOC, the first metal columns and the first surface of the first rewiring layer, and partially exposes the first metal columns;
a second rewiring layer disposed on a top surface of the first plastic sealing layer;
wherein the second rewiring layer comprises a second wiring dielectric layer and a second wiring metal layer located in the second wiring dielectric layer, wherein the second wiring metal layer is electrically connected to the first metal columns and the SOC;
first external interfaces located on a surface of the second wiring metal layer away from the first metal columns;
at least one top chip, located on the second surface of the first rewiring layer and electrically connected to the first wiring metal layer; and
a second plastic sealing layer, covering the top chip and the second surface of the first rewiring layer.

2. The system-integrated 3DFO structure according to claim 1, wherein the first chip is built with a different generation technology than the system wafer is.

3. The system-integrated 3DFO structure according to claim 1, wherein the SOC further comprises:
a second dielectric layer and second metal pads, formed over the system wafer, wherein the second metal pads are formed within the second dielectric layer and electrically connected to the system wafer;
in-chip metal columns, formed over the second metal pads and electrically connected to some of the second metal pads;
a first dielectric layer and first metal pads, formed over the first chip, wherein the first metal pads are located in the first dielectric layer and electrically connected to the first chip, wherein the first dielectric layer and the second dielectric layer are attached to the first metal pads and the second metal pads;
an in-chip plastic sealing layer, covering a sidewall of the first chip, sidewalls of the in-chip metal columns and the second dielectric layer, partially exposing a bottom surface of the in-chip metal columns;
an in-chip rewiring layer, formed over the in-chip plastic sealing layer, wherein the in-chip rewiring layer comprises an in-chip wiring dielectric layer and an in-chip wiring metal layer which is located in the in-chip wiring dielectric layer and electrically connected to the in-chip metal columns; and
an external interface, formed on a surface of the in-chip wiring metal layer away from the in-chip metal columns.

4. The system-integrated 3DFO structure according to claim 3, wherein a spacing between two adjacent ones of the first metal pads is less than 5 μm, and a spacing between two adjacent ones of the second metal pads is less than 5 μm.

5. The system-integrated 3DFO structure according to claim 3, wherein dimensions of the first metal pads are not the same as dimensions of the second metal pads.

6. The system-integrated 3DFO structure according to claim 3, wherein the in-chip metal columns are formed on peripheral ones of the second metal pads.

7. The system-integrated 3DFO structure according to claim 3, wherein a front surface of the first chip has first signal interfaces electrically connected to the first metal pads, and wherein the first metal pads have an arrangement different from an arrangement of the first signal interfaces; wherein a front surface of the system wafer has second signal interfaces electrically connected to the second metal pads, and wherein the second metal pads have an arrangement different from an arrangement of the second signal interfaces.

8. The system-integrated 3DFO structure according to claim 3, wherein a material of the first dielectric layer comprises one or more of silicon oxide, silicon nitride, silicon oxynitride, carbon nitride, and polymer, and wherein a material of the second dielectric layer comprises one or more of silicon oxide, silicon nitride, silicon oxynitride, carbon nitride, and polymer.

9. The system-integrated 3DFO structure according to claim 1, wherein the system wafer comprises a thinned and flattened substrate.

10. The system-integrated 3DFO structure according to claim 1, wherein the at least one top chip comprises N chips, where N is an integer and N≥2.
